(19) United States
(12) Patent Application Publication
(10) Pub. No.: US 2009/0001470 A1
(43) Pub. Date: Jan. 1, 2009

(54) METHOD FOR FORMING ACUTE-ANGLE SPACER FOR NON-ORTHOGONAL FINFET AND THE RESULTING STRUCTURE

(76) Inventors: Brent A. Anderson, Jericho, VT (US); Edward J. Nowak, Essex Junction, VT (US); Kathryn T. Schonenberg, Wappingers Falls, NY (US)

Correspondence Address: EDWARD W. BROWN, 46 PHEASANT RUN, WILTON, CT, 06897, US

(21) Appl. No.: 11/768,257

(22) Filed: Jun. 26, 2007

(51) Int. Cl. H01L 29/786; H01L 21/336

(52) U.S. Cl. 257/351; 257/347; 438/151; 257/E29.273; 257/E21.411

(57) ABSTRACT

In a method of fabricating a semiconductor finFET transistor for an integrated circuit chip comprising 1) the formation of at least one fin body on the surface of a substrate and 2) the formation of a gate on said fin body in a non-orthogonal orientation relative to the body thereby creating acute angle regions at the crossover of the gate on the body, and 3) the formation of a protective material in the acute angle regions so as to prevent damage to the gate during subsequent fabrication steps. The structure of the finFET transistor comprises such a transistor with protective material in the acute angle regions at the crossover of the gate on the body.

### FIELD OF THE INVENTION

The present invention relates to the fabrication of integrated circuits and, more particularly, the fabrication and structure of a FinFET of short channel performance.

### BACKGROUND OF THE INVENTION

The trend in semiconductor manufacture continues to be reducing the size of semiconductor devices while, at the same time, increasing their density on the chip. From a performance standpoint, the trend is to increase the speed of the devices even with a greater in number devices on the chip.

To be able to continue to reduce the size and density of the devices on the chip, the dimensions of the devices have to be made smaller and their configuration have to be changed. One example of a change in configuration is to utilize freestanding silicon rails as the body of the transistor. These bodies are perpendicular to the plane defined by the wafer surface and are called “Fins”. Double-gated transistors constructed with such fins can provide lower leakage currents and have smaller gate lengths over what is presently available. U.S. Pat. No. 6,252,284 to Muller, et al., which is assigned to the same assignee as this application, discloses such a FinFET device and the method of making the device.

It is well known in the art that in semiconductor crystals, such as silicon, the mobility of holes and electrons is a function of the crystalline plane in which the channel of the transistor is fabricated. With silicon, electrons have their greatest mobility in {100}-equivalent planes while holes have their greatest mobility in {110}-equivalent planes. Other types of semiconductors, such as gallium arsenide, have different electron/hole mobilities in different planes.

FinFET devices on substrates, such as silicon or silicon-on-insulator (SOI), are fabricated so that appropriate crystalline planes are utilized in forming a n-channel FinFET and in forming a p-channel FinFET. Such a FinFET is disclosed in U.S. Pat. No. 6,794,718 to Nowak, et al., which is assigned to the same assignee as this application and which is incorporated herein by reference. In this patent, an integrated circuit is described in which first and second FinFETs with channel regions disposed on first and second crystalline planes. The first freestanding semiconductor body of the FinFET with a n-type channel region is disposed in a first crystalline plane that has greater electron mobility than the second crystalline plane. The second freestanding semiconductor body of the FinFET with a p-type channel region is disposed on a second crystalline plane that has a greater hole mobility than that of the first freestanding semiconductor body. Both FinFETs are formed with gate electrodes at non-orthogonal angles relative to the semiconductor bodies thereby creating acute and obtuse angles at the crossing regions of the bodies and the gates. Since the gate length is defined by the width of the gate electrode overlaying the semiconductor body, it is extremely important that the method of fabricating the FinFET provides absolute control over the dimensions of the gate electrode at the crossover region.

### SUMMARY OF THE INVENTION

Accordingly, it is an object of the present invention to provide a method and structure of a FinFET with non-orthogonal angles to accurately maintain the dimensions of the gate electrode at the crossover region during fabrication and, in turn, the accuracy of the channel length.

Another object of the present invention is to accurately maintaining the dimensions of the gate electrode without complicating the fabrication process.

These and other objects and advantages are achieved by the present invention of protecting the acute angles of the non-orthogonal FinFET relative to its gate after forming the protection and during the remaining fabrication of the FinFET. More specifically, insulating material, such as silicon oxide or silicon nitride, is disposed at least in the acute angle regions at the crossover regions of the FinFET body and the gate. Acute angle regions are regions whose angle of the finFET relative to the gate is less than 90 %

One skilled in the art will understand that the FinFET structure described by the present inventive technique will be part of a larger semiconductor device incorporating a plurality of semiconductor structures. For example, the semiconductor structure could be part of a p-channel or n-channel MOSFET integrated circuit, or part of a CMOS which incorporates both p-channel and n-channel MOSFETs integrated circuit which embody the present inventive technique.

### BRIEF DESCRIPTION OF THE DRAWINGS

The features of the present invention will be apparent with reference to the following description and drawings of FIGS. 1-16 of the structure and method of fabricating the present invention, wherein:

FIG. 1 is a cross-sectional view of a substrate on which is disposed a layer of a semiconductor material on which is disposed an insulating layer.

FIG. 2 is a cross-sectional view of the substrate and layers of FIG. 1 with an additional layer of a material which will serve as mandrels in the fabrication of the FinFET.

FIG. 3 is a cross-sectional view of the substrate and layers of FIG. 2 with the mandrel layer being formed into two mandrels which, although not shown as such, are non-orthogonal to each other.

FIG. 4 is a cross-sectional view of the substrate and the two mandrels of FIG. 3 with sidewalls formed on each side of the mandrels.

FIG. 5 is a cross-sectional view with four freestanding semiconductor bodies which are formed from the semiconductor layer and the insulating layer using the sidewalls of FIG.4 as a mask.

FIG. 6 is a plan view of the four freestanding semiconductor bodies of FIG. 5 showing their angled orientation on the substrate.

FIG. 7 is a cross-sectional view of the four freestanding semiconductor bodies of FIG. 5 with a gate material covering the bodies.

FIG. 8 is a plan view of the four freestanding semiconductor bodies of FIG. 7 showing their non-orthogonal angled orientation on the substrate with acute and obtuse angles relative to their gates

FIG. 9 is a cross-sectional view of the four freestanding semiconductor bodies with the gate material of FIG. 8 and with an additional thin conformal insulating layer disposed on the sides of the semiconductor bodies and the gates.

FIG. 10 is a plan view of the four freestanding semiconductor bodies with the gate material of FIG. 8 and with an additional thin conformal insulating layer disposed on the sides of the semiconductor bodies and the gates and in the acute angle regions.

FIG. 11 is a plan view of the four freestanding semiconductor bodies with the gate material of FIG. 8 and with the thin conformal insulating layer of FIG. 10 disposed as spacers only in the acute angle regions after over etching the straight side edges of the bodies and gates.

FIG. 12 is a plan view of the four freestanding semiconductor bodies with the gate material of FIG. 8 and with the thin conformal insulating layer of FIG. 10 disposed as spacers only along the side edges of the gate and in the acute angle regions after partially etching the straight side edges of the bodies and gates.

FIG. 13 is a plan view of the four freestanding semiconductor bodies and their gates as shown in FIG. 11 and showing further an ion implantation process step in which the acute angle spacers block the ions and protect the gate and, in turn, the channel.

FIG. 14 is a plan view of the four freestanding semiconductor bodies and their gates as shown in FIG. 11 and showing further a grown extension layer around the bodies which is preventing from bridging to the gate by the acute angle spacers.

FIG. 15 is a plan view of the four freestanding semiconductor bodies and their gates as shown in FIG. 12 and showing further an ion implantation process step in which the acute angle spacers block the ions and protect the gate and, in turn, the channel.

FIG. 16 is a plan view of the four freestanding semiconductor bodies and their gates as shown in FIG. 12 and showing further a grown extension layer around the bodies which is preventing from bridging to the gate by the acute angle spacers.

### DETAILED DESCRIPTION OF THE INVENTION

The background for the present invention involves non-orthogonal finFET semiconductor bodies, of herein silicon, relative to the gate. A {100} surfaced silicon wafer (not shown) is oriented with {100} planes at 22.5 degrees with respect to a vertical reference axis that lies along the plane of the upper surface of the wafer, which results in {110} planes having an orientation that lies 22.5 degrees in the opposite direction of the vertical reference axis. Freestanding silicon bodies will be formed along these respective planes according to whether they are used to build n-type or p-type FETs. The gate electrode is in a direction orthogonal to the vertical reference axis of the wafer but non-orthogonal relative to the silicon bodies. The gate length is defined by the width of the gate electrode overlying a silicon body, while the channel length is defined by the gate length, minus the distance that the source and drain junctions extend under the gate.

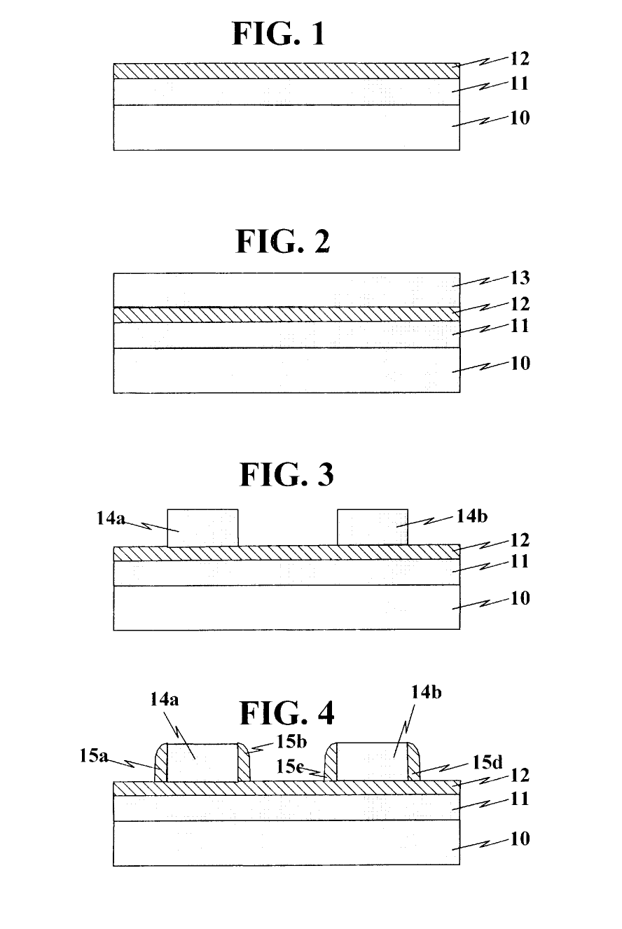

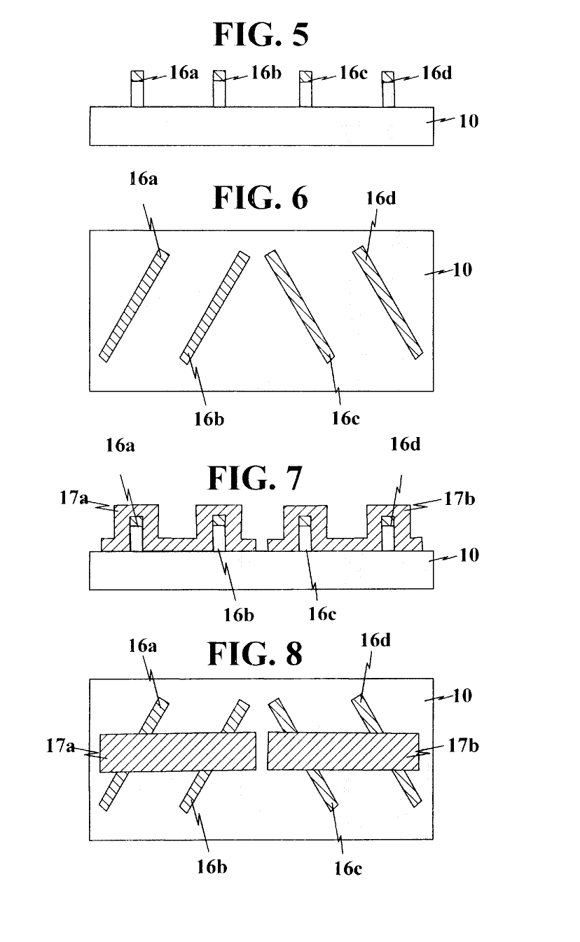

To fabricate the finFETs of the present invention, a silicon-on-insulator (SOI) substrate wafer 10, which is partially shown in FIG. 1 and having disposed there on a semiconductor layer 11, herein silicon, and an insulating layer 12, herein silicon oxide. As shown in FIG. 2, a thick mandrel layer 13, herein polysilicon, is disposed on the insulating layer 12 and, using a photomask (not shown), the polysilicon 13, as shown in FIG. 3, is etched to the silicon oxide layer 12 to form to mandrels 14a and 14b. Next, sidewalls 15a, 15b, 15c, and 15d are formed on the mandrel 14a and 14b, as shown in FIG. 4, and with the mandrels removed, the sidewall serve as masks (not shown) for the forming silicon fin bodies 16a, 16b, 16c, and 16d from the silicon layer 11 and the oxide layer 12 on the substrate 10, as shown in cross-sectional in FIG. 5 and plan view in FIG. 6

It will be noted in FIG. 6 that silicon bodies 16a and 16b are oriented so that the resulting channels of the FET will be along the {100} plane of the silicon layer and are used to form n-type finFETs. The silicon bodies 16c and 16d are oriented so that the resulting channels of the FET will be along the {110} plane of the silicon layer and are used to form p-type finFETs. After forming the freestanding silicon bodies, selected bodies are suitably doped (not shown) with the appropriate dopant while masking the non-selected bodies. Next, a gate insulating layer (not shown), such as silicon oxide, is formed in the silicon bodies, preferable by thermal oxidation. Then, as shown in the cross-sectional view of FIG. 7 and the plan view of FIG. 8, gate electrodes 17a and 17b, typically polysilicon, are formed on the silicon oxide and the a gate length in this orientation is the width of the gate electrode.

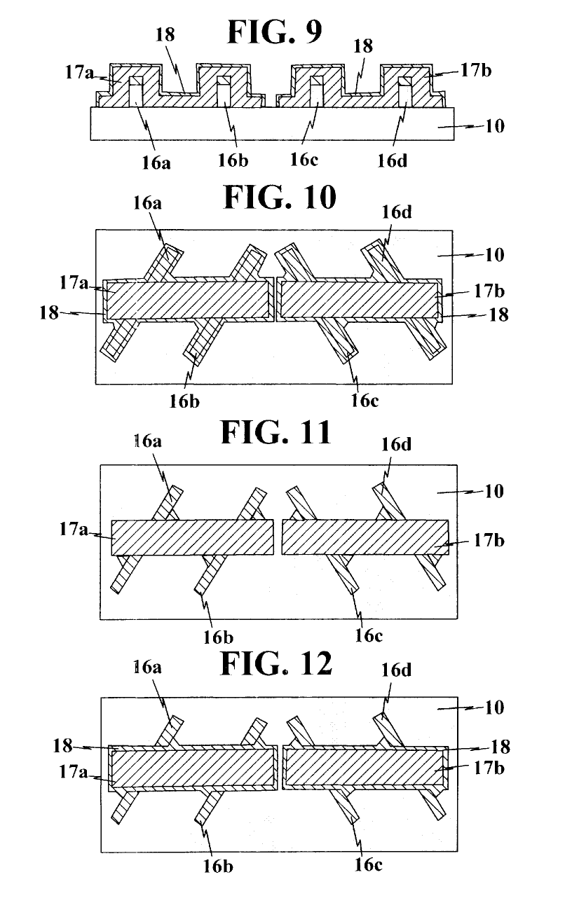

Gate length, and the channel length are critical parameters in determining the speed and proper function of FETs and, in particular, finFETs. Therefore, in accordance with the present invention, the gates 17a and 17b will be protected during the latter part of the finFET fabrication. As shown in cross-sectional view of FIG. 9 and the plan view of FIG. 10, a conformal gate protective layer 18, herein silicon nitride, is deposited around the sidewalls of the silicon fin bodies 16a-16d and gates 17a-17b. After removing selected portions of the layer 18 by herein directional over etching with a known etchant for silicon nitride, the layer 18 is removed along the straight edges, leaving the protective material 18 in acute angle regions 19a, 19b, 19c and 19d at gate 17a and acute angle regions 20a, 20b, 20c, and 20d at gate 17b. Preferably, the directional etching is accomplished by an anisotropic etching technique, such as reactive ion etching, to remove the protective material 18. Alternatively, as another embodiment of the present invention, the protective layer 18 can be partially over etched, as shown in FIG. 12, to remove the layer along the sidewalls of the silicon fin bodies 16a-16d but not along the gates 17a and 17b nor in the acute angle regions 19a-19d and 20a-20d.

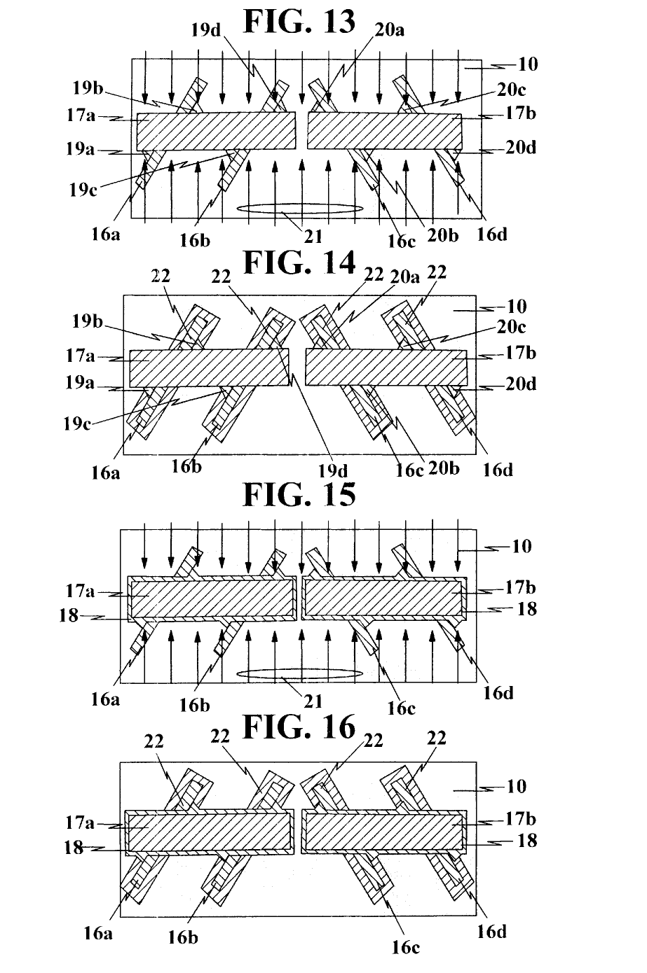

In subsequent processing in the fabrication of the finFET of the present invention, the acute angle regions 19a-19d and 20a-20d protect the gate width and, hence the channel length from either damage or a change in dimensions, such as by ion implantation as shown by the arrows 21 in FIG. 13 with only the acute angle regions protected and, as shown in FIG. 15, with the acute angle regions and the gate sidewalls 18 protected. Similarly, the growth of extensions 22, such as SiGe as shown in FIG. 14, with only the acute angle regions protected, or, as shown in FIG. 16, with the gate sidewalls also protected from bridging to the gates in the acute angle regions, thereby preventing damage to the gates 17a and 17b. Furthermore the channel length is protected from poorly controlled source and drain dosage that could result, without the present invention, from ions being implanted into an acute angle region at the gate/fin intersection. Without the present invention, a shadowing of the ion implant by the acute angle regions and poor etch definition resulting from the acute angle regions could result in non-uniform source and drain implantation. The protection of acute angle regions removes this possibility.

Although the invention has been shown and described with respect to certain embodiments, equivalent alterations and modifications will occur to those skilled in the art upon reading and understanding this specification and drawings. In doing so, those skilled in the art should realize that such alterations and modifications are within the spirit and scope of the present invention as set forth in the appended claims and equivalents thereon.

What is claimed is:

1. A method of fabricating a semiconductor finFET transistor comprising:
providing a substrate;
forming a first vertical surface on said substrate;
forming a second vertical surface on said substrate intersecting said first vertical surface at an acute angle;
depositing a conformal material on said substrate and said first and second surfaces; and
directionally etching said material leaving a portion of said material at least at said intersection forming said acute angle.

2. In a method of fabricating a semiconductor finFET transistor for an integrated circuit chip comprising the steps of:
providing a substrate;
forming at least one fin body having straight edges on the surface of said substrate;
forming a gate having straight edges on said fin body in a non-orthogonal orientation relative to the body thereby creating acute angle regions and obtuse angle regions at the crossover of the gate on the body; and
forming protective material in the acute regions so as to prevent damage to the gate during subsequent fabrication steps.

3. The method of claim 2 wherein a protective layer also is formed along the straight edges of said gate.

4. The method of claim 2 wherein said protective material is formed by depositing the material on said substrate, said body and said gate, followed by anisotropically over etching to remove all of the material from the straight edges of said body and said gate, thereby leaving the material only in the acute angle regions.

5. The method of claim 2 wherein said protective material is formed by depositing the material on said substrate, said body and said gate, followed by partial etching to remove all of the material from the straight edges of said body including the obtuse angle region and to partially remove some of the material from the straight edges of said gate but to remove none of the material in the acute angle regions.

6. The method of claim 2 wherein said protective material is an insulating material.

7. The method of claim 6 wherein said protective material is silicon nitride.

8. The method of claim 2 wherein said protective material in the acute angle regions prevent damage to the channel length during ion implantation.

9. The method of claim 2 wherein said protective material in the acute angle regions prevent bridging to the gate during the formation of an extension to the fin body.

10. The method of claim 1 where said substrate is silicon-on-insulator (SOI).

11. In a semiconductor finFET transistor for an integrated circuit chip, comprising:
a substrate;
at least one fin body having straight edges deposed on the surface of said substrate;
a gate having straight edges deposed on said fin body in a non-orthogonal orientation relative to the body thereby creating acute angle regions at the crossover of the gate on the body; and
a protective material deposed in at least the acute angle regions, whereby damage will be prevented during subsequent fabrication steps.

12. The finFET transistor of claim 11 wherein said protective material is deposed along the straight edges of said gate with a portion of the material being partially removed.

13. The finFET transistor of claim 11 with the protective material deposed in the acute angle regions wherein an extension is deposed in said substrate adjacent said body.

14. The finFET transistor of claim 11 with the protective material deposed in the acute angle regions wherein ions are implanted in the substrate adjacent said body.

15. The finFET transistor of claim 11 with the protective material deposed in the acute angle regions wherein source and drain regions are deposed in the substrate adjacent said body.

16. A semiconductor finFET transistor for an integrated circuit chip, comprising:
a substrate having a crystalline plane favoring the mobility of electrons;
a fin body having straight edges deposed on the surface of said substrate and overlying said crystalline plane;
a gate having straight edges deposed on said fin body in a non-orthogonal orientation relative to the body thereby creating acute angle regions at the crossover of the gate on the body;
a protective material deposed in at least the acute angle regions;
an extension deposed adjacent said body; and
a source and a drain deposed on opposite sides of said body and a channel deposed in-between said source and said drain and on said crystalline plane.

17. The substrate of said finFET transistor of claim 16 is comprises a second crystalline plane favoring the mobility of holes, and the fin body of a second finFET transistor is deposed with straight edges on the surface of said substrate and overlying said crystalline plane.

18. The second finFET transistor of claim 17 having a source and a drain deposed on opposite sides of the body of the transistor and a channel deposed in-between said source and said drain and on said second crystalline plane.

19. The finFET transistor of claim 16 wherein said protective material also is deposed along the straight edges of said gate with a portion of the material being partially removed.

20. The finFET transistor of claim 16 wherein an extension is deposed adjacent the fin body of the transistor.
